(19) United States
(12) Patent Application Publication
(10) Pub. No.: US 2013/0209736 A1
(43) Pub. Date: Aug. 15, 2013

(54) COATED ARTICLE HAVING ROCK LIKE PATTERN AND METHOD FOR MANUFACTURING THE SAME

(71) Applicants: DA-HUA CAO, Shenzhen City (CN); XU LIU, Shenzhen City (CN)

(72) Inventors: DA-HUA CAO, Shenzhen City (CN); XU LIU, Shenzhen City (CN)

(21) Appl. No.: 13/655,635

(22) Filed: Oct. 19, 2012

(30) Foreign Application Priority Data
Feb. 13, 2012 (CN) 201210031108.8

(51) Int. Cl. B32B 9/04; C23C 14/34; B32B 33/00

(52) U.S. Cl. 428/142; 204/192.1

(57) ABSTRACT

An article includes a substrate, a color layer formed on the substrate, and a transparent layer formed on the color layer. The color layer includes a second matte region and a second mirror-like region, the second mirror-like region present an appearance like cracks in rocks. The transparent layer includes a third matte region and a third mirror-like region, the third matte region corresponds to the second matte region and covers the second matte region, the third mirror-like region corresponds to the second mirror-like region and covers the second mirror-like region. A method for manufacturing the article is also provided.

### BACKGROUND

1. Technical Field

The exemplary disclosure generally relates to a coated article having rock like patterns and a method for manufacturing the coated article.

2.Description of Related Art

Metal substrates may be decorated by layers having an appearance similar to rocks. The layer may be a paint layer formed by spray painting, or a molded plastic layer. The plastic layer forms a rock like pattern thereon when being molded. However, the paint layers or the plastic layers have limited resemblance to a lifelike rock. Additionally, the paint layers or the plastic layers have low hardness and poor abrasion resistances.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary disclosure. Moreover, in the drawings, like reference numerals designate corresponding parts throughout the several views. Wherever possible, the same reference numbers are used throughout the drawings to refer to the same or like elements of an embodiment.

FIG. 1 is a schematic view of a first exemplary embodiment of a coated article.

FIG. 2 is a cross sectional view of the coated article of FIG. 1 taken along line II-II.

FIG. 3 is a cross sectional view of a second exemplary embodiment of a coated article.

FIG. 4 is a schematic view of a vacuum sputtering device for manufacturing the coated article.

### DETAILED DESCRIPTION

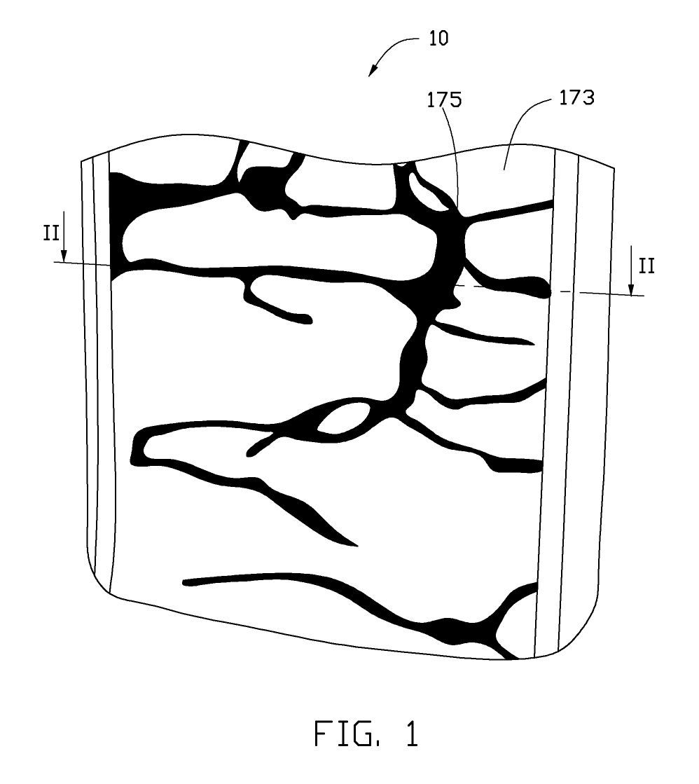

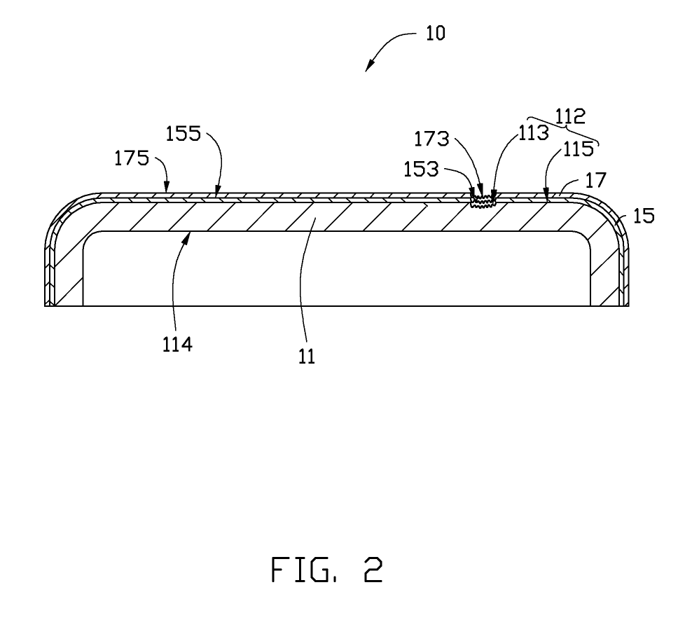

Referring to FIGS. 1 and 2, a first exemplary embodiment of a coated article 10 includes a substrate 11, a color layer 15 formed on the substrate 11, and a transparent layer 17 formed on the color layer 15.

The substrate 11 includes a first surface 112 and an opposite second surface 114. The first surface 112 includes at least one first matte region 113 and one first mirror-like region 115. The first matte region 113 may be formed by laser engraving, chemically etching, sandblasting, or the like. The roughness (Ra) of the first matte region 113 is about 0.3 nm-0.8 nm. The first mirror-like region 115 has a gloss (Gs 60°) of about 100-105. The substrate 11 can be made of stainless steel, magnesium alloy, aluminum alloy, or titanium alloy.

The color layer 15 is a chromium-carbon (Cr—C) layer formed by physical vapor deposition. The color layer 15 includes at least one second matte region 153 and one second mirror-like region 155. The second matte region 153 corresponds to the first matte region 113 and directly covers the first matte region 113. The second mirror-like region 155 corresponds to the first mirror-like region 115 and directly covers the first mirror-like region 115. The thickness of the color layer 15 is about 2 μm-4 μm.

The transparent layer 17 is a silicon-aluminum-oxygen (SiAlOₓ) layer formed by physical vapor deposition. In the SiAlOₓ layer, the “x” satisfies the following relationship: 1≦x≦3.5. The transparent layer 17 includes at least one third matte region 173 and one third mirror-like region 175. The third matte region 173 corresponds to the second matte region 153 and directly covers the second matte region 153. The third mirror-like region 175 corresponds to the second mirror-like region 155 and directly covers the second mirror-like region 155. The roughness (Ra) of the third matte region 173 is about 0.4 nm-1.0 nm. The transparency of the transparent layer 17 is about 30%-80%. The thickness of the transparent layer 17 is about 1 μm-2 μm.

The third mirror-like region 175 has a gloss (Gs 60°)of about 93-96. The third matte region 173 has an L* value between about 40 to about 45, an a* value between about 0 to about 3, and a b* value between about 0 to about 3 in the CIE L*a*b* (CIE LAB) color space, and presents a black color. The third mirror-like region 175 has an L* value between about 36 to about 40, an a* value between about 0 to about 2, and a b* value between about 0 to about 2 in the CIE LAB color space, and also presents a black color. The difference of the L* value between the third matte region 173 and the third mirror-like region 175 is about 3-8.

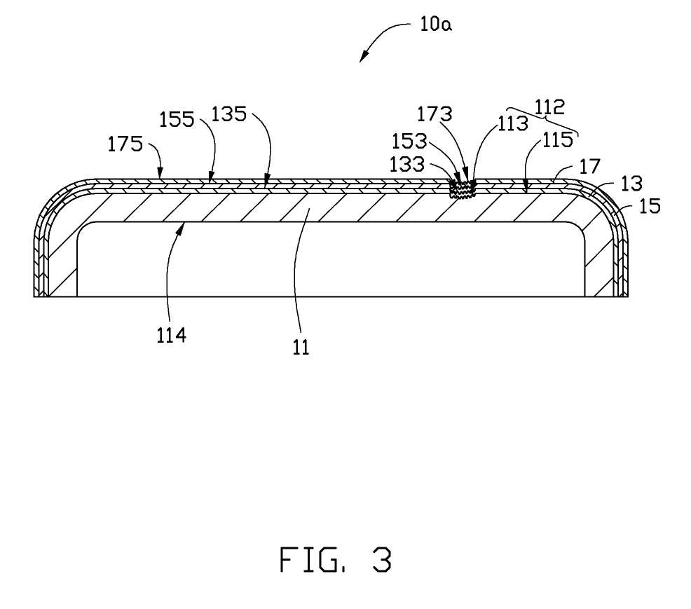

Referring to FIGS. 3, a second exemplary embodiment of a coated article 10a further includes a bonding layer 13 formed between the substrate 11 and the color layer 15 to improve the bond between the substrate 11 and the color layer 15. The bonding layer 13 is a chromium layer formed by physical vapor deposition. The thickness of the bonding layer 13 is about 0.1 μm-0.2 μm. The bonding layer 13 includes at least one fourth matte region 133 and one fourth mirror-like region 135. The fourth matte region 133 corresponds to the first matte region 113 and directly covers first matte region 113. The fourth mirror-like region 135 corresponds to the first mirror-like region 115 and directly covers the first mirror-like region 115.

When being irradiated, the second matte region 153 and the third matte region 173 diffuse reflected the light, and the second mirror-like region 155 and the third mirror-like region 175 mirror reflect the light, as a result the regions of the third mirror-like region 175 have a black color darker than the color of the regions of the third matte region 173. The regions of the coated article 10 correspond to the third matte region 173 present a rock like pattern, and the regions correspond to the third mirror-like region 175 present an appearance like cracks in rocks. Furthermore, the third mirror-like region 175 has high brightness, which enhances the visual effect of the rock like appearance of the coated article 10. Additionally, the transparent layer 17 formed by physical vapor deposition can also enhance the hardness and abrasion resistance of the coated article 10.

Alternatively, the color layer 15 can be titanium-carbon-nitrogen (TiCN) layer, titanium-oxygen-nitrogen (TiON) layer, chromium-oxygen (CrO) layer, zirconium-carbon-nitrogen (ZrCN) layer, or titanium-aluminum-nitrogen (TiAlN) layer. The color layer 15 may have a color different than black.

Alternatively, the transparency layer 17 may be a silicon dioxide (SiO₂) layer or an aluminum oxide (Al₂O₃) layer.

A method for manufacturing the coated article 10 includes at least the following steps:

A substrate 11 is provided. The substrate 11 includes a first surface 112 and an opposite second surface 114. The substrate 11 may be made of stainless steel, magnesium alloy, aluminum alloy, or titanium alloy.

The substrate 11 is polished. After being polished, the first surface 112 has a gloss (Gs 60°)of about 95-98.

The at least one first matte region 113 is formed on the first surface 112 by laser engraving, sandblasting, or etching. The first surface 112 further includes a first mirror-like region 115 which is un-treated by laser engraving, sandblasting, or etching. The first mirror-like region 115 presents an appearance like cracks in rocks. The roughness (Ra) of the first matte region 113 is about 0.3 nm-0.8 nm.

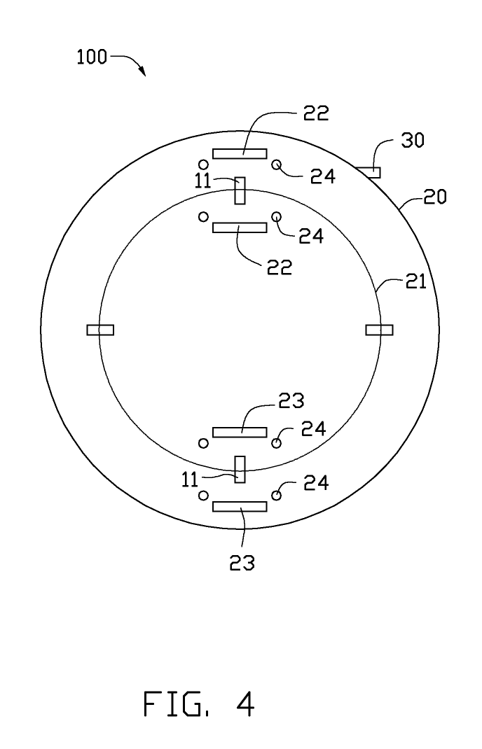

Referring to FIG. 4, a vacuum sputtering device 100 is provided. The vacuum sputtering device 100 includes a chamber 20, and a vacuum pump 30 connected to the chamber 20. The vacuum pump 30 is used to evacuate the chamber 20. The vacuum sputtering device 100 further includes a rotating bracket 21, two first targets 22 and two second targets 23 mounted therein, and a plurality of gas inlets 24. The rotating bracket 21 rotates the substrate 11 in the chamber 20 relative to the first targets 22 and the second targets 23. The two first targets 22 face each other, and are located on opposite two sides of the rotating bracket 21. The two second targets 23 face each other, and are located on opposite two sides of the rotating bracket 21. In the exemplary embodiment, the first targets 22 are Cr targets, the second targets 23 are aluminum-silicon (Si—Al) composite targets, wherein the mass percentage of elemental Si is about 60% to about 90%, the mass percentage of elemental Al is about 10% to about 40%.

A color layer 15 is deposited on the first surface 112 by vacuum sputtering. The color layer 15 is a Cr—C layer. The substrate 11 is mounted on the rotating bracket 21 in the chamber 20. The chamber 20 is evacuated to about 4×10⁻³Pa to about 6×10⁻³ Pa. The internal temperature of the chamber 20 is about 130° C. to about 180° C. Argon gas may be used as a working gas and is fed into the chamber 20 at a flow rate from about 160 standard cubic centimeters per minute (sccm) to about 250 sccm. Acetylene gas may be used as a reaction gas and is fed into the chamber 20 at a flow rate from about 160 sccm to about 220 sccm. The first targets 22 in the chamber 20 are applied a power between about 14 kW to about 17 kW. A bias voltage applied to the substrate 11 may be between about −100 volts (V) and about −150 V. Depositing of the color layer 15 may take about 60 minutes to 120 minutes. The color layer 15 has a thickness of about 2 μm to about 4 μm. The region of the color layer 15 covered on the first matte region 113 of the substrate 11 defines the second matte region 153, the region of the color layer 15 covered on the first mirrolike region 115 of the substrate 11 defines the second mirrolike region 155.

A transparent layer 17 is formed on the color layer 15 by vacuum sputtering. The temperature of the inside of the chamber 20 is about 130° C. to about 180° C. Argon gas may be used as a working gas and is fed into the chamber 20 at a flow rate from about 160 sccm to about 250 sccm. Oxygen gas may be used as a reaction gas and is fed into the chamber 20 at a flow rate from about 100 sccm to about 150 sccm. The second targets 23 in the chamber 20 are applied a power between about 14 kW to about 17 kW. A bias voltage applied to the substrate 11 may be between about −100 V and about −150 V. Depositing of the color layer 15 may take about 20 minutes to 40 minutes. The transparent layer 17 has a thickness of about 1 μm to about 2 μm. The region of the transparent layer 17 covered on the second matte region 153 of the color layer 15 defines the third matte region 173, the region of the transparent layer 17 covered on the second mirrolike region 155 of the color layer 15 defines the third mirror-like region 175.

In the second exemplary embodiment, the method for manufacturing the coated article 10a further comprises a step of forming a bonding layer 13 between the substrate 11 and the color layer 15 by vacuum sputtering. The bonding layer 13 is a chromium layer. Argon gas may be used as a working gas and is fed into the chamber 20 at a flow rate from about 160 sccm to about 250 sccm. The first targets 22 in the chamber 20 are applied a power between about 13 kW to about 16 kW. A bias voltage applied to the substrate 11 may be between about −100 V and about −150 V. Depositing of the bonding layer 13 may take about 5 minutes to 12 minutes. The bonding layer 13 has a thickness of about 0.1 μm to about 0.2 μm. The region of the bonding layer 13 covered on the first matte region 113 of the substrate 11 defines the fourth matte region 133, the region of the bonding layer 13 covered on the first matte region 113 of the substrate 11 defines the substrate 11 defines.

Alternatively, the step of forming the first matte region 113 can be omitted, and the color layer 15 can be laser engraved, sandblasted or etched to form the second matte region 153. The color layer 15 may be formed by painting or chemical deposition.

### Example 1

The substrate 11 was provided. The substrate 11 included a first surface 112 and an opposite second surface 114. The substrate 11 was made of stainless steel.

The substrate 11 was polished. After being polished, the first surface 112 had a gloss of about 96.

The first matte region 113 was formed on the first surface 112 by laser sandblasting. The roughness (Ra) of the first matte region 113 was about 0.8 nm.

In depositing the color layer 15: the chamber 20 was evacuated to about 4×10⁻³ Pa. The temperature of the inside of the chamber 20 was about 150° C. The flow rate of argon gas was about 180 sccm. The flow rate of acetylene gas was about 180 sccm. A power about 14 kW was applied to the first targets 22. A bias voltage applied to the substrate 11 was about −100 V. The depositing of the color layer 15 lasted about 60 minutes. The thickness of the color layer 15 was about 2 μm.

In depositing the transparent layer 17: the temperature of the inside of the chamber 20 was about 150° C. The flow rate of acetylene gas was about 120 sccm. The flow rate of argon gas was about 180 sccm. A power about 14 kW was applied to the second targets 23. A bias voltage applied to the substrate 11 was about −100 V. The depositing of the color layer 15 lasted about 60 minutes. In the second targets 23, the mass percentage of elemental Si is about 80%, the mass percentage of elemental Al is about 20%. The transparency of the transparent layer 17 was about 80%. The roughness (Ra) of the third matte region 173 was about 1.0 nm. The thickness of the transparency layer 17 was about 1 μm.

The third mirror-like region 175 had a gloss of about 94. The third matte region 173 had an L* value between about 42, an a* value between about 0.6, and a b* value between about 1 in the CIE L*a*b* (CIE LAB) color space, and presents a black color. The third mirror-like region 175 had an L* value between about 36, an a* value between about 1, and a b* value between about 1.2 in the CIE L*a*b* (CIE LAB) color space, and also presents a black color.

### Example 2

The substrate 11 was provided. The substrate 11 included a first surface 112 and an opposite second surface 114. The substrate 11 was made of aluminum alloy.

The substrate 11 was polished. After being polished, the first surface 112 had a gloss of about 97. A first matte region 113 was formed on the first surface 112 by laser sandblasting. The roughness (Ra) of the first matte region 113 was about 0.4 nm.

In depositing a color layer 15: the chamber 20 was evacuated to about 4×10⁻³ Pa. The temperature of the inside of the chamber 20 was about 130° C. The flow rate of argon gas was about 200 sccm. The flow rate of acetylene gas was about 200 sccm. A power about 16 kW was applied to the first targets 22. A bias voltage applied to the substrate 11 was about −120 V. The depositing of the color layer 15 lasted about 60 minutes. The thickness of the color layer 15 was about 3 μm.

In depositing a transparent layer 17: the temperature of the inside of the chamber 20 was about 130° C. The flow rate of acetylene gas was about 120 sccm. The flow rate of argon gas was about 180 sccm. The second targets 23 were applied a power about 16 kW. A bias voltage applied to the substrate 11 was about −120 V. The depositing of the color layer 15 lasted about 20 minutes. In the second targets 23, the mass percentage of elemental Si was about 70%, and the mass percentage of elemental Al was about 30%. The transparency of the transparent layer 17 was about 50%. The roughness (Ra) of the third matte region 173 was about 0.7 nm. The thickness of the transparent layer 17 was about 1.5 μm.

The third mirror-like region 175 had a gloss of about 95. The third matte region 173 had an L* value between about 45, an a* value between about 1.0, and a b* value between about 0.8 in the CIE LAB color space, and present a black color. The third mirror-like region 175 had an L* value between about 40, an a* value between about 1.5, and a b* value between about 1.5 in the CIE LAB color space, and also present a black color.

### Example 3

The substrate 11 was provided. The substrate 11 included a first surface 112 and an opposite second surface 114. The substrate 11 was made of magnesium alloy.

The substrate 11 was polished. After being polished, the first surface 112 had a gloss of about 96. A first matte region 113 was formed on the first surface 112 by laser sandblasting. The roughness (Ra) of the first matte region 113 was about 0.5 nm.

In depositing a color layer 15: the chamber 20 was evacuated to about 4×10⁻³ Pa. The temperature of the inside of the chamber 20 was about 130° C. The flow rate of argon gas was about 220 sccm. The flow rate of acetylene gas was about 220 sccm. The first targets 22 were applied a power about 17 kW. A bias voltage applied to the substrate 11 was about −120 V. The depositing of the color layer 15 lasted about 120 minutes. The thickness of the color layer 15 was about 4 μm.

In depositing a transparent layer 17: the temperature of the inside of the chamber 20 was about 140° C. The flow rate of acetylene gas was about 140 sccm. The flow rate of argon gas was about 220 sccm. The second targets 23 were applied a power about 23 kW. A bias voltage applied to the substrate 11 was about −120 V. The depositing of the color layer 15 lasted about 40 minutes. In the second targets 23, the mass percentage of elemental Si is about 75%, the mass percentage of elemental Al is about 25%. The transparency of the transparent layer 17 was about 60%. The roughness (Ra) of the third matte region 173 was about 0.8 nm. The thickness of the transparency layer 17 was about 2 μm.

The third mirror-like region 175 had a gloss of about 93. The transparency third matte region 173 had an L* value between about 43, an a* value between about 1.2, and a b* value between about 2.0 in the CIE LAB color space, and present a black color. The third mirror-like region 175 had an L* value between about 38, an a* value between about 1.5, and a b* value between about 1.5 in the CIE LAB color space, and also present a black color.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article having rock like patterns pattern, comprising:
a substrate;
a color layer formed on the substrate, the color layer comprising a second matte region and a second mirror-like region, the second mirror-like region presenting an appearance like cracks in rocks; and
a transparent layer formed on the color layer, the transparent layer comprising a third matte region and a third mirror-like region, the third matte region corresponding to the second matte region and covering on the second matte region, the third mirror-like region corresponding to the second mirror-like region and covering on the second mirror-like region.

2. The coated article as claimed in claim 1, wherein the difference of L* value in the CIE L*a*b* color space between the third matte region and the third mirror-like region is about 3-8.

3. The coated article as claimed in claim 1, wherein the color layer is a CrC layer, a TiCN layer, a TiON layer, a CrO layer, a ZrCN layer, or a TiAlN layer.

4. The coated article as claimed in claim 1, wherein the transparent layer is a SiAlOₓ layer, wherein the “x” satisfies the following relationship: 1≦x≦3.5.

5. The coated article as claimed in claim 1, wherein the transparent layer is a SiO₂ layer or an Al₂O₃ layer.

6. The coated article as claimed in claim 4, wherein the roughness (Ra) of the third matte region is about 0.3 nm-0.8 nm.

7. The coated article as claimed in claim 4, wherein the transparency of the transparent layer is about 30%-80%.

8. The coated article as claimed in claim 4, wherein the third mirror-like region has a gloss of about 93-96.

9. The coated article as claimed in claim 4, wherein the color layer is CrC layer, the transparent layer is SiAlOₓ layer, the third matte region has an L* value between about 40 to about 45, an a* value between about 0 to about 3, and a b* value between about 0 to about 3 in the CIE L*a*b* color space.

10. The coated article as claimed in claim 9, wherein the third mirror-like region has an L* value between about 36 to about 40, an a* value between about 0 to about 2, and a b* value between about 0 to about 2 in the CIE L*a*b* color space.

11. The coated article as claimed in claim 1, wherein the coated article further includes a bonding layer formed between the substrate and the color layer.

12. The coated article as claimed in claim 11, wherein the bonding layer is a chromium layer.

13. The coated article as claimed in claim 11, wherein the bonding layer includes a fourth matte region and a fourth mirror-like region.

14. The coated article as claimed in claim 1, wherein the substrate includes a first matte region and a first mirror region.

15. The coated article as claimed in claim 14, wherein the roughness (Ra) of the first matte region is about 0.4 nm-1.0 nm.

16. The coated article as claimed in claim 14, wherein the first mirror region has a gloss of about 100-105.

17. A method for manufacturing an article, comprising:
providing a substrate;
polishing the substrate;
forming a color layer on the substrate, the color layer comprising second matte region and second mirror-like region, the second mirror-like region presenting an appearance like cracks in rocks; and
forming a transparent layer on the color layer, the transparent layer comprising a third matte region and a third mirror-like region, the third matte region corresponding to the second matte region and covering on the second matte region, the third mirror-like region corresponding to the second mirror-like region and covering on the second mirror-like region.

18. The method as claimed in claim 17, wherein the second matte region is formed by laser engraving, sandblasting or etching.

19. The method as claimed in claim 17, wherein the transparent layer is formed by physical vapor deposition.

20. The method as claimed in claim 17, wherein the method further comprises a step of treating the substrate by laser engraving, sandblasting or etching to form a first matte region between the steps of polishing the substrate and forming the color layer.
